(19) United States
(12) Patent Application Publication
(10) Pub. No.: US 2025/0112624 A1
(43) Pub. Date: Apr. 3, 2025

(54) TUNABLE MULTI-PHASE RESONANT CLOCK GENERATION AND DISTRIBUTION

(71) Applicant: Intel Corporation, Santa Clara, CA (US)

(72) Inventors: Susnata MONDAL, Hillsboro, OR (US); Mozhgan MANSURI, Portland, OR (US)

(21) Appl. No.: 18/374,967

(22) Filed: Sep. 29, 2023

(51) Int. Cl. H03H 11/02; G06F 1/08; G06F 1/10

(52) U.S. Cl. CPC H03H 11/02; G06F 1/08; G06F 1/10

(57) ABSTRACT

Disclosed are multi-phase coupled resonant clock generation circuits that include magnetic coupling compensation techniques. Also disclosed are resonant distribution circuits that can use inductors spaced more closely to one another.

### TECHNICAL FIELD

Embodiments of the invention relate to the field of multi-phase clocking and more specifically, to the fields of multi-phase clock generation and distribution.

### BRIEF DESCRIPTION OF THE DRAWINGS

The disclosure may best be understood by referring to the following description and accompanying drawings that are used to illustrate embodiments of the invention. In the drawings:

FIG. 1A is a diagram showing a conventional coupled-resonator quad hybrid (CRQH) generator circuit.

FIG. 1B is an example layout diagram showing coupled inductors used for the CRQH circuit of FIG. 1A.

FIG. 2A is a schematic diagram showing a coupled inductor resonator based quad hybrid (CRQH) generator in accordance with some embodiments.

FIG. 2B is a diagram showing the resonant circuit of FIG. 2A in more detail in accordance with some embodiments.

FIG. 3 is a diagram showing amplitude and phase response curves for the I and Q path signals in the CRQH circuit of FIGS. 2A and 2B in accordance with some embodiments.

FIGS. 4A and 4B are diagrams illustrating compact, overlapped low-k coupled inductors using partial magnetic-flux compensation in accordance with some embodiments.

FIG. 5 is a diagram showing a coupled resonant quadrature generator having an I-Q signal averaging circuit in accordance with some embodiments.

FIG. 6 is a block diagram showing an eight phase CRQH generator in accordance with some embodiments.

FIG. 7A is a diagram illustrating a conventional Resonant clocking distribution circuit.

FIG. 7B is a diagram showing a resonant quad distribution circuit in accordance with some embodiments.

FIG. 7C is a diagram showing another resonant quad distribution circuit in accordance with some embodiments.

FIG. 7D is a diagram showing yet another resonant quad distribution circuit in accordance with some embodiments.

FIG. 7E is a diagram showing over-lapping inductors with flux cancellation for use in a quad distribution circuit in accordance with some embodiments.

FIG. 8 is a diagram showing a compact 8-phase clock distribution architecture in accordance with some embodiments.

FIG. 9 is a diagram illustrating an example computing system incorporating some of the embodiments disclosed herein.

### DETAILED DESCRIPTION

Multi-phase clock generation, such as quadrature and eight-phase generation, is important for many different applications such as coherent wireless (e.g., Wi-Fi, Cellular), wireline (e.g., PCIe, UCIe), and optical communications. Quadrature generation circuits are widely used, for example, with quarter-rate transceivers, full-phase interpolators, and quadrature mixing wireless transceivers. They are typically implemented with quadrature hybrid circuits. A quadrature (or 90 degree) hybrid circuit is a transmission circuit that receives an input signal such as a high frequency clock signal and from that signal, generates a version of the signal that is 90 degrees out of phase from the input signal. It provides at its output the original signal (I path), along with the 90 degree out-of-phase signal (Q path). Conventional quadrature generation circuits are typically bulky, lossy, single-ended, and usually require a 50 Ohm interface. Moreover, to support multiple frequency bands/standards, they are often required to operate over a wide frequency range, which can be especially challenging to achieve with low power and area constraints, as well as with jitter and gain error requirements.

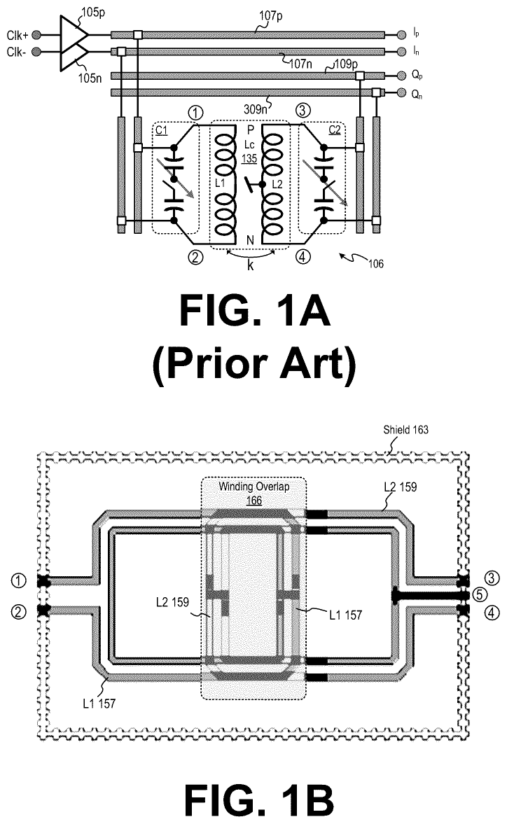

FIG. 1A is a diagram showing a conventional coupled-resonator quad hybrid (CRQH) generator circuit (also referred to as quad hybrid or quad hybrid generator). The quad generator circuit includes differential clock drivers 105 (105p, 105n), I path differential signal lines 107 (107p, 107n), Q path differential lines 109 (109p, 109n) and a quad resonator formed from coupled inductor pair 135 (L1, L2) and tunable capacitors C1, C2, all coupled together as shown. A high frequency (e.g., 2 GHz. or higher) differential clock Clk (Clk+, Clk−) is driven by the drivers 105 through the I path 107 and into a drive (also referred to as primary side) port (1, 2) of the resonator circuit, which generates a 90 degree out-of-phase version of the I path signal through an output (also referred to as secondary side) port (3, 4) onto the Q path lines 109. In this way, differential quadrature I (Ip, In) and Q (Qp, Qn) clocks may be generated.

FIG. 1B is an example layout diagram showing the coupled inductors L1, L2 used for the resonator circuit. As shown, inductor L1 (157) is a conductive loop partially overlapping the second inductor L2 (159). They are implemented as wires, or traces, on spaced apart (e.g., adjacent) metal stack layers in an integrated circuit. The inductors also have an inductive bias trace 161 and an interference shield structure 163, as shown. They overlap one another at an overlap region 166. Among other things, the amount of overlap, as well as how they are positioned relative to each other, determines how well they are coupled to one another. This is quantified using a coupling factor (K), which is a value between 0 and 1 where 1 indicates perfect coupling, i.e., all flux generated from the primary coil penetrates the secondary (or coupled) coil. For a good 90 degree phase relationship between the I and Q signals, it is generally desirable to have a relatively lower K value, although this, of course, will depend upon other design factors.

In operation, the inductors (L1, L2) and capacitors (C1, C2) form a resonant LC tank with an associated “Q” factor. The Q factor is a measure of the quality of a resonant (tank) circuit. A “high-Q” circuit has mostly reactive components (inductive and capacitive), with low resistance. It resonates strongly, with little damping (low loss).

By tuning the capacitors, the frequency of the generated quadrature signals (I, Q) may in turn be tuned. Such resonant hybrid generators have the potential to be both area and power efficient since they use a coupled-inductor to generate the differential quadrature phases without, for example, requiring a 50 Ohm interface. Unfortunately, however, to maintain good quadrature amplitude matching, the product of the coupling factor (K) and tank circuit quality factor (Q) needs to be maintained, which is hard to achieve, especially over desired operational frequency ranges. For example, it is difficult to maintain I and Q signal amplitude balance over different operating frequencies.

Accordingly, in some embodiments, resonant quadrature generation techniques and features are presented addressing these and other challenges. For example, in some embodiments, tuning circuits are provided that improve operating frequency ranges. In some embodiments, a partial magnetic-flux compensated overlapped inductor design is also presented that improves resonator area efficiency. In addition, a jitter reducing technique for both quadrature output phases is also presented. Moreover, techniques for multi-phase generation other than 90 degree phase shift generation are presented as well.

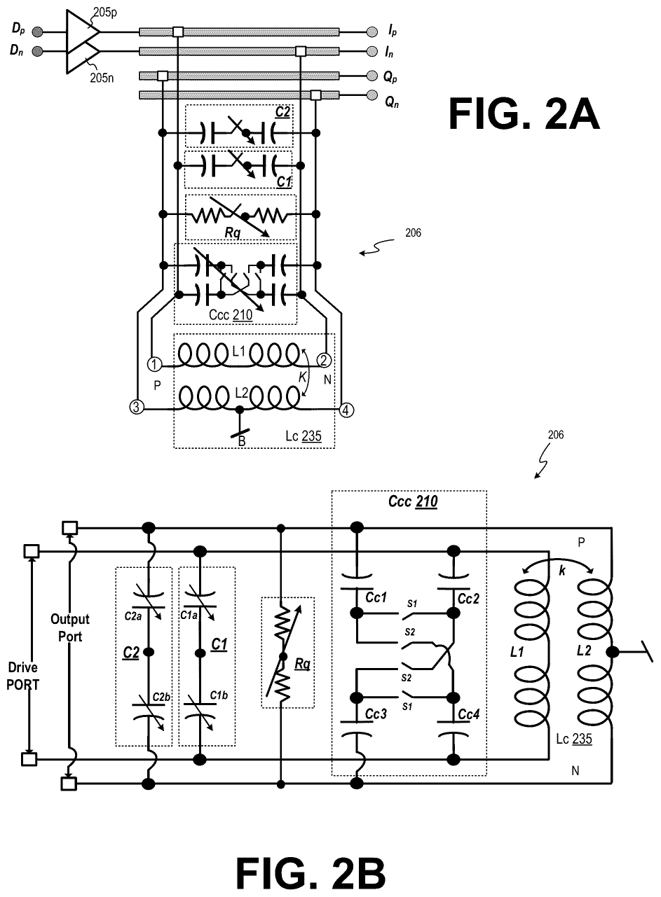

With reference to FIGS. 2A-4B, wide-tuning-range coupled-resonator-based quadrature phase generation circuit embodiments are presented. In some embodiments, they may incorporate compact overlapped inductors, capacitive coupling tuning, quality (Q) factor tuning, or combinations of any one or more of these approaches.

FIG. 2A is a schematic diagram showing a coupled inductor resonator based quad hybrid (CRQH) generator in accordance with some embodiments. The circuit includes differential drivers 205, I and Q path lines (207, 209) and a quad resonator circuit 206, coupled as shown to generate quadrature I and Q signals. The resonator circuit 206 includes drive (primary) port and output (secondary) port tuning capacitors (C1, C2 respectively) and coupled inductor pair 235 (L1 on drive port and L2 on output port). The resonator circuit also includes a tuning resistor Rq coupled to the output port and a switchable-cross-coupled capacitor circuit (SCCC) 210 coupled to both the drive and output ports. FIG. 2B shows the resonant circuit including the cross-coupled capacitor 210 in better detail. (Note that the capacitors and inductors are shown split into two sections, attributable to this being a differential implementation but for simplicity, the components may be referenced as a single element. Along these lines, any indicated capacitor, resistor, or inductor could actually be implemented with multiple components to achieve desired values and desired tunability.)

The tunable drive and output side capacitors (C1, formed from C1a and C1b and C2, formed from C2a and C2b) are tunable, e.g., by a control circuit (not shown) to adjust resonant operating frequency. As with the cross-coupled capacitors, they may be tuned (adjustment of their capacitances) through any suitable manner such as by switching different combinations of series and/or parallel connected capacitor legs to achieve suitable capacitance values. The tunable resistor Rq, which is coupled to the resonant output serves to adjust the quality factor (Q), also for resonant frequency tuning. It too may be adjusted using any suitable variable resistance technique such as with switchable resistor legs.

The switchable cross-coupled capacitors (formed from Cc1, Cc2, Cc3, Cc4) are used to adjust the effective inductive K factor. That is, depending on switch configuration, the cross-coupled capacitors will add or subtract a capacitive coupling compensation component (Kc) to/from the inherent inductive coupling factor (K). The effective coupling factor K′ can be expressed as K′=K+/−Kc.

When the S1 switches are on (closed) and the S2 switches are off (open), capacitors Cc1 and Cc2 are coupled between the “P” end of the drive side and the “P” end of the output side. Likewise, capacitors Cc3 and Cc4 are coupled between the “N” end of the drive side and the “N” end of the output side. With this configuration, the effective coupling factor (K) is decreased, more so as the values of Cc increase. On the other hand, when switches S1 are off and S2 are on, cross-coupled capacitors Cc2 and Cc3 will be coupled between the “P” end of the drive side and the “N” end of the output side. while capacitors Cc1 and Cc4 will be coupled between the “N” end of the drive side and the “P” end of the output side. With this configuration, the effective coupling factor (K) is increased, more so as the values of Cc increase. Finally, when all of the switches are turned off, the K is not affected by the cross-coupled capacitor structure.

With resonant systems, it is desirable to have low gain error between the I and Q signals. The I-Q gain ratio at the quadrature frequency is 1/k′Q, Therefore, to maintain low I-Q gain error, using a switchable and tunable cross-coupled capacitor structure coupled to the coupled inductors, the effective coupling factor (k′) can be proportionally increased (even with a fixed k) by tuning the cross-coupled capacitors as the tank Q reduces at lower frequencies. It is worth noting that this technique provides an elegant solution to tune the effective coupling factor of a coupled resonator simply by using tunable switchable capacitor configurations, where the coupled-inductor geometry fixes the magnetic coupling factor (K) itself. It is also worth pointing out that this technique can be used to tune the effective coupling factor of coupled resonators used in other applications such as wideband/dual-band systems, etc.

The output side tuning resistor Rq may be used to maintain the quality factor (Q) across the tuning range. The quality factor of the complex zero in the I-path response, and hence the I-Q gain matching, depends strongly on the Q value (Qo) for the output port. Selectively reducing Q (de-Qing) on the output side of the resonator at higher tuning frequencies (e.g., with higher quality factor from turned-off C1, C2 and CC switch caps) helps to perform I-Q gain equalization by maintaining effective Q2. In typical scenarios, selective secondary (output) side de-Qing is better than de-Qing both sides that would otherwise cause significant I-Q gain reduction and thus reduce power efficiency.

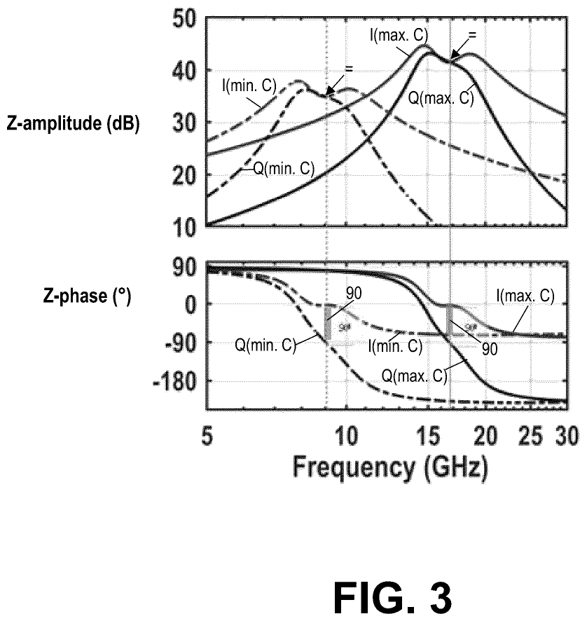

FIG. 3 is a diagram showing amplitude and phase response curves for the I and Q path signals at min. and max. capacitance values for resonator 206. For good quadrature clock generation, the I and Q signals should be very close to 90 degrees out of phase from each other and at the same time, they should have equivalent amplitudes. In this example, it can be seen that the circuit is effectively tuned for both the lower and higher ends of its operating frequency range. At the lower end (min. capacitance settings) at 9 GHZ (the tuned frequency), the I and Q signals are 90 degrees out-of-phase, and their amplitudes are equal to each other. Likewise, at the upper end (max capacitance setting), the resonant circuit is tuned for approximately 16.5 GHz where the I and Q signals are 90 degrees out-of-phase and their amplitudes are equivalent.

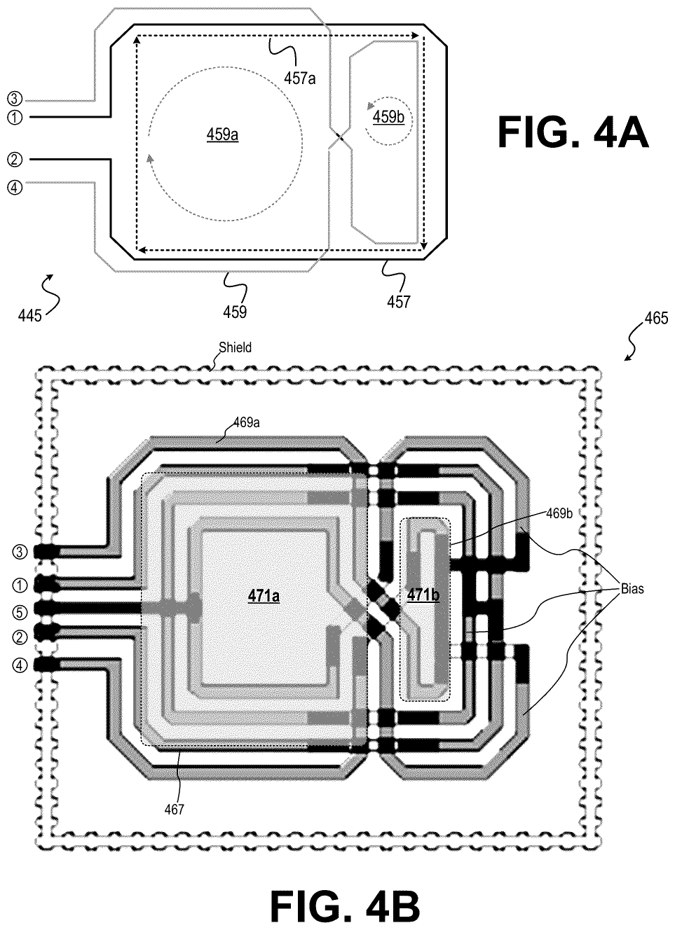

FIGS. 4A and 4B are diagrams illustrating compact, overlapped low-k coupled inductor designs using partial magnetic-flux compensation in accordance with some embodiments. FIG. 4A is a simplified diagram of a coupled inductor pair 445 illustrating its primary (drive) side inductor coil 457 and secondary (output) side coil 459, showing its clockwise/anti-clockwise signal flow. As can be seen, the primary coil 457 has a generally rectangular shape, while the secondary coil 459 has an asymmetrical figure-eight type shape. It essentially has two distinct regions corresponding to the secondary loop sections 459a and 459b. The larger region (459a), as indicated, is inductively aligned with the signal direction for the primary coil 457. On the other hand, the smaller region corresponding to 459b is inductively aligned against (opposite signal direction) the primary coil 457. (Note that while it may not be clear from the figure, each coil is formed from a continuous conductor (e.g., wire or trace) between its respective terminals. The second coil's wire does not come into contact with itself where it crosses over to form the figure-eight shape. Accordingly, it may be implemented in multiple metal stack layers of an IC, e.g., using vias or the like. The cross-over “jumper” portion, for example, could be implemented within the same layer that houses the primary coil.)

Together, the primary and secondary coils (inductors) form a partial magnetic-coupling compensation structure where the inductors can be overlapped, sharing the same footprint. It should be appreciated that this is not complete magnetic-flux cancellation with a 180 degree turn at the center of one coil. Rather, the 180 degree turn is skewed towards one side for partial magnetic-flux cancelation. This helps realize low coupling factors (K) required for CRQH operation (e.g., k or K′=0.2 or so), improving the area efficiency. Moreover, as with the embodiments shown in FIGS. 4A, 4B, the overlapped inductors allow both the drive (primary) and output (secondary) ports feed points (1, 2 and 3, 4) to be physically close, thereby making the cross-coupled capacitive implementation more feasible.

FIG. 4B is a diagram showing a particular implementation 465 of the coupled inductors of FIG. 4A. Shown here are primary inductor 467 and secondary inductor 469, along with their aligned overlap region 471a and non-aligned overlap region 471b. Also shown in this figure are bias traces and a shield, as indicated.

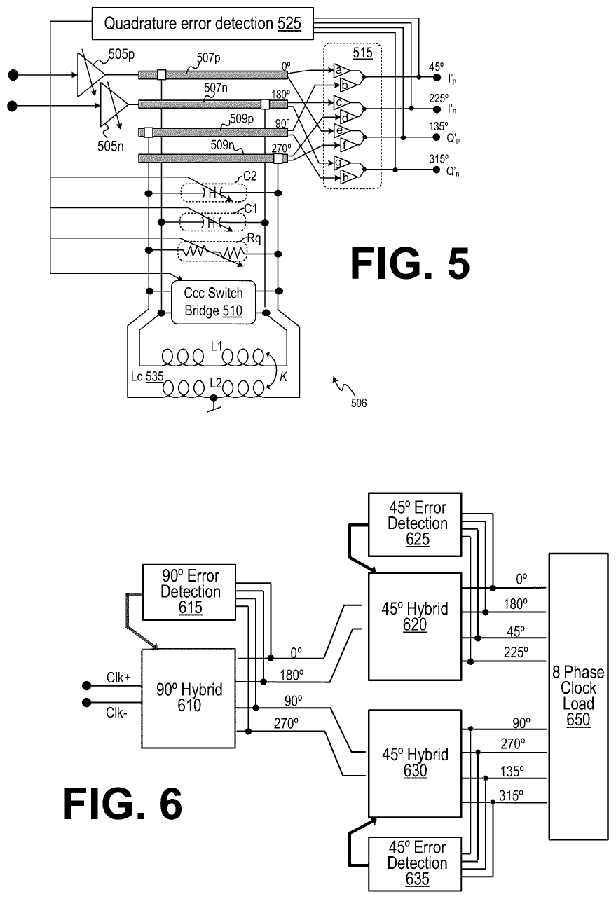

FIG. 5 is a diagram showing a coupled resonant quadrature generator having an I-Q signal averaging circuit in accordance with some embodiments. With the depicted embodiment, jitter is reduced by averaging signals from the I and Q paths with each other. The circuit includes a CRQH circuit as previously discussed. In this implementation, the circuit includes capacitive tuning (C1, C2) for both primary and secondary sides of coupled inductor pair 535, along with a tunable de-Qing resistance coupled to the output (secondary) side and a tunable SCCC 510 coupled to both the primary and secondary inductor sides, as illustrated. The quad generator circuit also includes signal averaging drivers (inverters in this embodiment) 515, which generate the averaged I and Q output signals, labeled as I′ and Q′. It also includes quad error detection/control circuitry 525 for controlling the tuning of the capacitors, resistor and SCCC to maintain accurate 90 degree phase differences between the four outputs.

The signal averaging drivers 515 help to equalize existing jitter filtering in the I and Q paths. In general, the I-path has first-order out-of-band filtering in contrast with the Q-path, which has second-order filtering. Without the signal averaging circuitry 515, there would be a jitter reduction imbalance between the signal paths. The signal averaging driver circuitry includes four driver pairs (a/b, c/d, e/f, g/h), each with their outputs coupled together, resulting at their outputs an averaging of their input signals. Since the Q path typically has inherently better jitter filtering, each of the two Q path components (Qp, Qn) are separately averaged together with each of the two I path components (Ip, In) as shown. In this way, equalized jitter filtering in both I and Q paths may be achieved. The I′ and Q′ outputs are phase-shifted by 45 degrees, but this is not problematic since they have proper quadrature phase relationships with respect to each other. Moreover, as will be shown below, this technique may be used to create an 8-phase (or higher) resonator based clock generator.

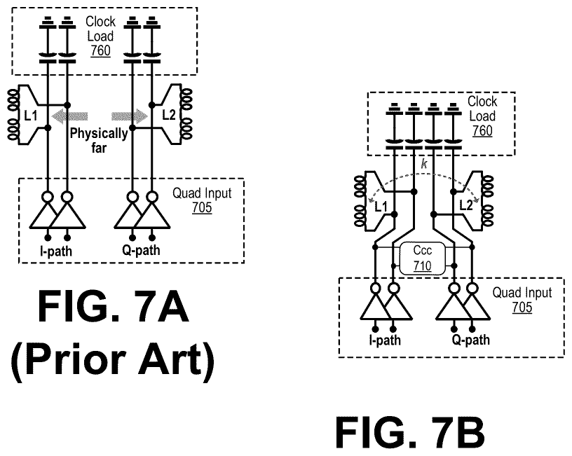

Turning to FIG. 6, CRQH architectures described above can also be used to generate multi-phase differential outputs with phase relationships other than 90 degrees. For example, any phase shift from 45 degrees to 135 degrees may be readily generated.

FIG. 6 is a block diagram showing an eight phase CRQH generator in accordance with some embodiments. Such a multi-phase generator may be used for several different applications such as a 1/8-rate I/O link with an 8-phase clock. As shown in this figure, the coupled resonator hybrid generator can be both used as 90 and 45 degree hybrids.

The eight-phase generator includes a 90 degree hybrid (CRQH) 610 such as are described above, along with an associated error detector 615, and two 45 degree hybrid generators (620, 630) with associated error detection circuits 625, 635, coupled as shown to provide eight 45-degree shifted clocks to an 8 phase load 650. In some embodiment the 45 degree hybrids can be implemented using the same CRQH architecture with tunable capacitor settings such that 45 degree out-of-phase signals are generated at the output. In some other embodiments, the 45 degree hybrids may be implemented using a 90 degree hybrid with partial signal driver averaging. For example, with the upper 45 degree hybrid (620), the signal averaging circuit could have two single-input drivers to simply buffer (pass on) the 0 and 180 degree signals to its outputs, along with two averaging driver pairs to average together the 0/90 and 180/270 signals, thereby outputing the depicted 0, 180, 45, and 225 degree signals. The lower 45 degree hybrid could be implemented similarly but instead working from the 90 and 270 degree signals generated by the 90 degree hybrid circuit 610 to generate the 90, 270, 135, and 315 degree signals. (Note that the drive (primary) and secondary (output) port outputs can contain slightly different third harmonics, which may need to be either filtered out or tolerated, e.g., if 45 degree hybrids are directly used to drive clock loads w/o further buffering.)

Resonant circuits may also be used for clock distribution. For example, they may be used for optical, wireline, and wireless links to improve energy efficiency, reduce jitter generation, and perform jitter filtering. For example, It may be especially beneficial to utilize resonant distribution in a final buffering stage of a clock distribution path since the final stage typically drives maximum clock loading and can consume a significant fraction of system power. Meanwhile, as link data rates increase, interleaving and multi-phase clocking are becoming more and more valuable, (e.g., quadrature clocking for a quarter rate system).

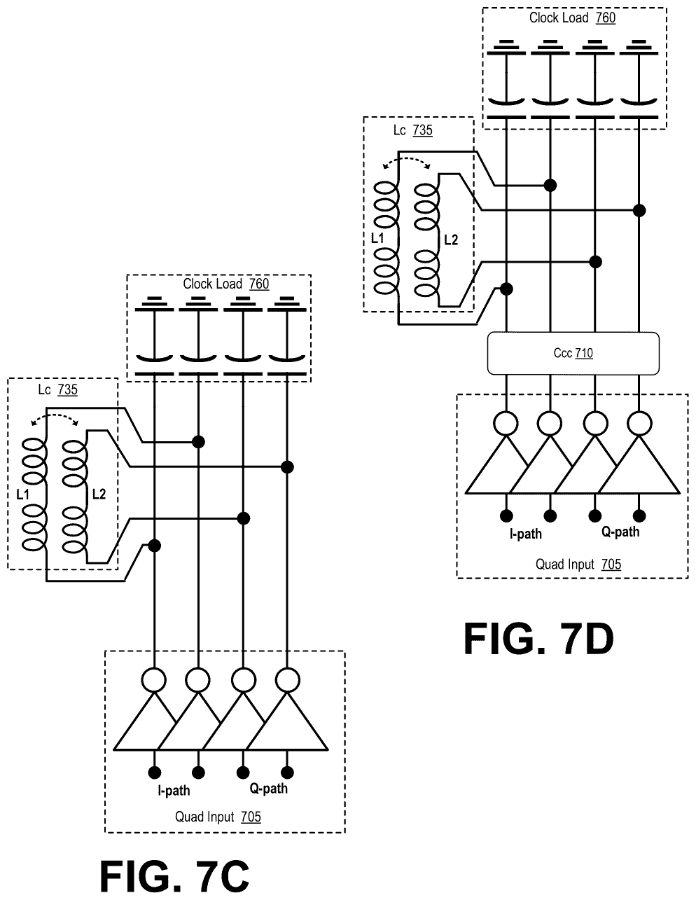

FIG. 7A is a diagram illustrating a conventional Resonant clocking distribution configuration. It has quad input (I, Q) drivers 705 to drive I and Q signals to a capacitive quad clock load 760 through I and Q signal lines and inductors 11, L2, as shown. The inductors and load capacitances make up the resonant part of this circuit and should be tuned a the frequency of the applied I and Q path input signals.

However, with multi-phase resonant clock driver systems, any parasitic magnetic coupling between the inductors such as with L1 and L2 can cause significant signal degradation since the coils are driven with different signal phases. Thus, as indicated in FIG. 7A, the coils are physically disposed away from each other, enough to avoid problematic parasitic coupling. This can make resonant drive distribution impractical for many IC applications where space for circuit components is at a premium. Accordingly, several different techniques are presented below to address these and other resonant clock distribution issues.

With reference to FIGS. 7B-7D, approaches for resonant clock distribution will now be described. In some embodiments, quad distribution channels may be implemented using more closely placed I-Q inductors than has before been practical. In some embodiments, they may use capacitive coupling compensation, magnetic flux compensated overlapped inductors, and/or overlapped inductors with capacitive coupling compensation.

FIG. 7B is a diagram showing a resonant quad distribution circuit in accordance with some embodiments. It is similar to the circuit of FIG. 7A except that it includes a cross-coupled capacitor circuit 710, which may be implemented with an SCCC as described above. In addition, since the SCCC is employed, the inductors (L1, L2) may be physically located more closely to one another without suffering from the adverse effects of parasitic magnetic coupling. As described above, parasitic magnetic coupling can be compensated using an SCCC. Therefore, the quadrature inductors can now be very closely packed, thereby improving area efficiency. Here, the capacitive coupling compensation circuit is used to reduce the parasitic coupling (K) between quadrature inductors by placing the cross-connected capacitors between quadrature path feed points. In some embodiments, the SCCC capacitors may be selected in the following manner. Assume each of the four cross-coupled capacitors (from FIG. 2B) is equal to 2 Cc, then Cc may be made equal to 2 kCL/(1−k) (where K is the absolute value of K and CL is load capacitance). (Note that the state of the SCCC switches S1 and S2 depends on the polarity of K.)

FIG. 7C is a diagram showing a resonant quad distribution circuit in accordance with some other embodiments. Here, a magnetic-coupling compensation method is applied where the inductors are overlapped and configured to provide magnetic flux cancellation. An exemplary inductor pair configuration is shown in FIG. 7E. Magnetic flux cancelation is achieved by employing a 180 degree turn in one of the two coils (secondary inductor in this example). By introducing the magnetic flux-canceled design, the mutual coupling of overlapped quadrature inductors can be reduced (e.g., K may be reduced from 0.6 to 0.05).

However, even after performing magnetic flux cancellation, some residual coupling (e.g., K<=0.05) can be unavoidable, which can still introduce significant I-Q gain and phase mismatch. Accordingly, the SCCC technique from FIG. 7B can be combined with the partial flux compensation approach of FIG. 7C, as is illustrated in FIG. 7D, to cancel the residual coupling. Therefore, by introducing the magnetic-flux-canceled overlapped inductor design and the capacitive coupling compensation technique, quadrature resonant clocking can be performed using a single inductor footprint. An example of such coupled inductors is shown in FIG. 7E.

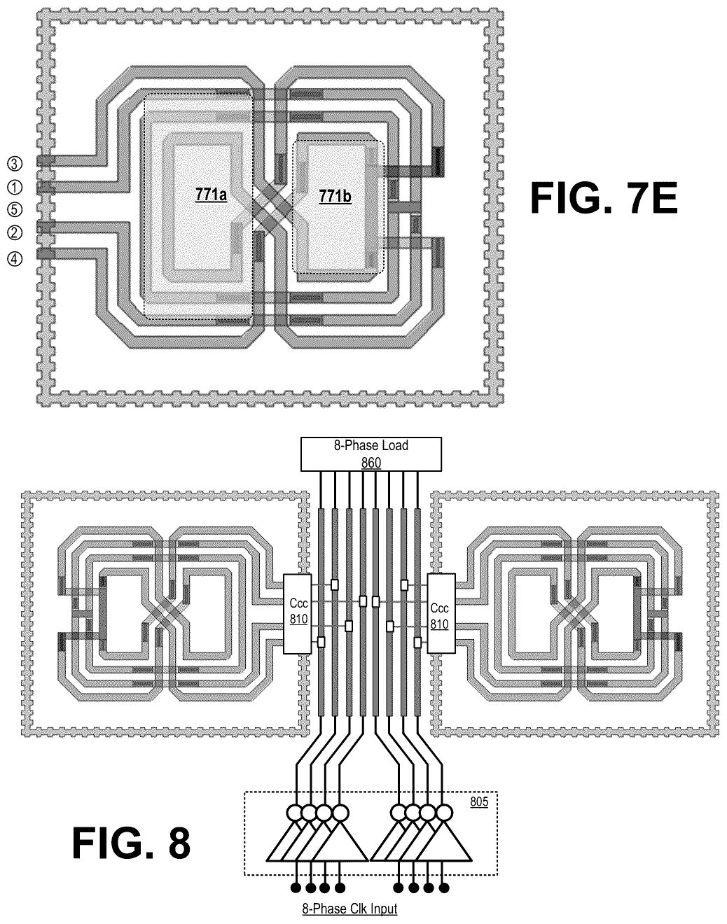

FIG. 8 is a diagram showing a compact 8-phase clock distribution architecture in accordance with some embodiments. This phase-matched resonant clock distribution implementation uses magnetic-flux-compensated overlapped inductors and capacitive coupling compensation as indicated. This structure may be generalized for distributing clocks with any phase relation. The techniques may especially be valuable for multi-phase resonant distribution, such as 8-phases for 8-way interleaved IO links.

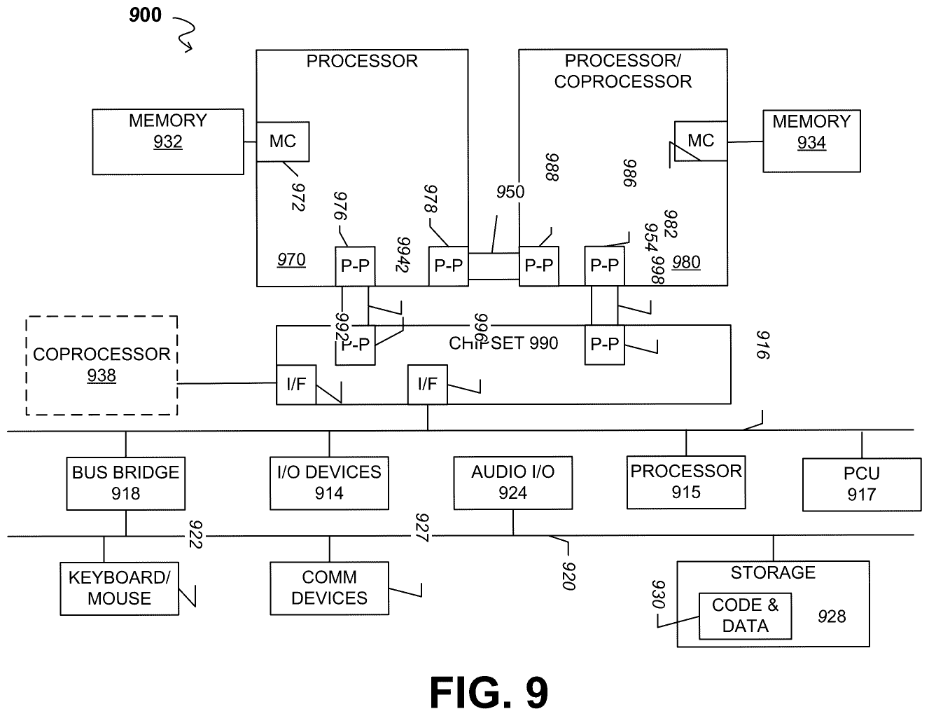

FIG. 9 is a diagram illustrating an example computing system incorporating some of the embodiments disclosed herein. Multiprocessor system 900 is an interfaced system and includes a plurality of processors including a first processor 970 and a second processor 980 coupled via an interface 950 such as a point-to-point (P-P) interconnect, a fabric, and/or bus. In some examples, the first processor 970 and the second processor 980 are homogeneous. In some examples, first processor 970 and the second processor 980 are heterogenous. Though the example system 900 is shown to have two processors, the system may have three or more processors, or may be a single processor system. In some examples, the computing system is implemented, wholly or partially, with a system on a chip (SoC) that has one or more chipssuch as in a multi-chip package, or it could be implemented in a multi-chip (or multi-chiplet) module comprising one or more processor chips, along in some cases with additional chips, in the same or in different package combinations.

Processors 970 and 980 are shown including memory controller (MC) circuitry 972 and 982, respectively. Processor 970 also includes interface circuits 976 and 978, along with core sets. Similarly, second processor 980 includes interface circuits 986 and 988, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 970, 980 may exchange information via the interface 950 using interface circuits 978, 988. MCs 972 and 982 couple the processors 970, 980 to respective memories, namely a memory 932 and a memory 934, which may be portions of main memory locally attached to the respective processors.

Processors 970, 980 may each exchange information with a network interface (NW I/F) 990 via individual interfaces 952, 954 using interface circuits 976, 994, 986, 998. The network interface 990 (e.g., one or more of an interconnect, bus, and/or fabric, and in some examples is a chipset) may optionally exchange information with a coprocessor 938 via an interface circuit 992. In some examples, the coprocessor 938 is a special-purpose processor, such as, for example, a high-throughput processor, a network or communication processor, compression engine, graphics processor, general purpose graphics processing unit (GPGPU), neural-network processing unit (NPU), embedded processor, or the like.

Note that some, or any combination, of the interface circuits, depending on the type of interconnection link (photonics, wireline, wireless) may utilize one or more of the compensated CRQH multi-phase generators and/or compensated I-Q distribution circuits disclosed herein. For example, quadrature phase generators are used for interleaving and quadrature amplitude modulation in optical (silicon photonics, VCSEL (vertical-cavity surface-emitting laser)-based discrete photonics, etc.), wireline (PCIe, UCIe, etc.), and wireless (millimeter-wave cellular, Wi-Fi, etc.) systems.

A shared cache (not shown) may be included in either processor 970, 980 or outside of both processors, yet connected with the processors via an interface such as P-P interconnect, such that either or both processors' local cache information may be stored in the shared cache if a processor is placed into a low power mode.

Network interface 990 may be coupled to a first interface 916 via interface circuit 996. In some examples, first interface 916 may be an interface such as a Peripheral Component Interconnect (PCI) interconnect, a PCI Express interconnect, or another I/O interconnect. In some examples, first interface 916 is coupled to a power control unit (PCU) 917, which may include circuitry, software, and/or firmware to perform power management operations with regard to the processors 970, 980 and/or co-processor 938. PCU 917 provides control information to one or more voltage regulators (not shown) to cause the voltage regulator(s) to generate the appropriate regulated voltage(s). PCU 917 also provides control information to control the operating voltage generated. In various examples, PCU 917 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 917 is illustrated as being present as logic separate from the processor 970 and/or processor 980. In other cases, PCU 917 may execute on a given one or more of cores (not shown) of processor 970 or 980. In some cases, PCU 917 may be implemented as a microcontroller (dedicated or general-purpose) or other control logic configured to execute its own dedicated power management code, sometimes referred to as P-code. In yet other examples, power management operations to be performed by PCU 917 may be implemented externally to a processor, such as by way of a separate power management integrated circuit (PMIC) or another component external to the processor. In yet other examples, power management operations to be performed by PCU 917 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 914 may be coupled to first interface 916, along with a bus bridge 918 which couples first interface 916 to a second interface 920. In some examples, one or more additional processor(s) 915, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 916. In some examples, second interface 920 may be a low pin count (LPC) interface. Various devices may be coupled to second interface 920 including, for example, a keyboard and/or mouse 922, communication devices 927 and storage circuitry 928. Storage circuitry 928 may be one or more non-transitory machine-readable storage media as described below, such as a disk drive or other mass storage device which may include instructions/code and data 930 and may implement the storage in some examples. Further, an audio I/O 924 may be coupled to second interface 920. Note that other architectures than the point-to-point architecture described above are possible. For example, instead of the point-to-point architecture, a system such as multiprocessor system 900 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

Illustrative examples of the technologies disclosed herein are provided below. An embodiment of the technologies may include any one or more, and any compatible combination of, the examples described below.

Example 1 is an apparatus that has first and second inductors and a switchable cross-coupled capacitor circuit. The first inductor has an input port with first and second ends. The second inductor is positioned relative to the first inductor to be magnetically coupled with the first inductor. The first and second inductors have an associated effective magnetic coupling factor that has an inductive component, and the second inductor has an output port with first and second ends. The switchable cross-coupled capacitor (SCCC) circuit is coupled to the input and output ports, for example, to adjust the effective magnetic coupling factor by adding or subtracting a capacitive coupling component to or from the inductive component.

Example 2 includes the subject matter of example 1, and wherein the SCCC circuit includes a plurality of capacitors switchably configured to be in one of multiple different configurations including a first configuration where at least a first capacitor from the plurality of capacitors is coupled between the first ends of the input and output ports.

Example 3 includes the subject matter of any of examples 1-2, and wherein with the first configuration, at least a second capacitor from the plurality of capacitors is coupled between the second ends of the input and output ports.

Example 4 includes the subject matter of any of examples 1-3, and wherein the multiple different configurations include a second configuration where at least a third capacitor from the plurality of capacitors is coupled between the first end of the input port and the second end of the output port.

Example 5 includes the subject matter of any of examples 1-4, and wherein with the second configuration, at least a fourth capacitor from the plurality of capacitors is coupled between the second end of the input port and the first end of the output port.

Example 6 includes the subject matter of any of examples 1-5, and further comprising a tunable resistance element coupled to the output port between its first and second ends.

Example 7 includes the subject matter of any of examples 1-6, and further comprising a first tunable capacitor coupled to the input port between its first and second ends and a second tunable capacitor coupled to the output port between its first and second ends.

Example 8 includes the subject matter of any of examples 17, and further comprising: (i) a driver coupled to the input port to drive into it a differential I-path clock, and (ii) a Q path line coupled to the output port to convey a differential Q path clock generated from the second inductor.

Example 9 includes the subject matter of any of examples 1-8, and further comprising signal averaging circuitry to average together components from the I and Q path clocks.

Example 10 includes the subject matter of any of examples 1-9, and wherein the I-path clock has first and second components 180 degrees out-of-phase from each other, and the Q-path clock has first and second components 180 degrees out-of-phase from each other, wherein the Q-path clock first component is 90 degrees out-of-phase from the I-path clock first component, the signal averaging circuitry comprising a driver pair to average together the first components from the I-path and Q-path clocks.

Example 11 includes the subject matter of any of examples 1-10, and wherein the first and second inductors overlap one another with a selected one of them having a wire that crosses over itself to facilitate a first flux region magnetically aligned with the other inductor and a second flux region magnetically unaligned with the other inductor, wherein the aligned and unaligned regions have different area sizes to provide partial magnetic flux compensation.

Example 12 includes the subject matter of any of examples 1-11, and wherein the selected one inductor is the first inductor.

Example 13 includes the subject matter of any of examples 1-12, and further comprising an error detection circuit coupled to the input and output ports and to the tunable SCCC to maintain desired phase relationships between a differential clock provided to the input port and a differential clock generated from the output port.

Example 14 is an apparatus that includes differential I and Q path lines, first and second inductors, and a switchable cross-coupled capacitor circuit (SCCC). The differential I-path signal lines are to receive a differential I-path clock. The differential Q-path signal lines receive a differential Q-path clock that is 90 degrees out-of-phase from the I-path clock. The first inductor is coupled to the I-path lines. The second inductor is coupled to the Q-path lines. The SCCC circuit is coupled to the I-path and Q-path lines to compensate for magnetic flux between the first and second inductors.

Example 15 includes the subject matter of example 14, and wherein the first and second inductors at least partially overlap one another.

Example 16 includes the subject matter of any of examples 14-15, and wherein a selected one of the first and second inductors has aligned and unaligned flux regions to facilitate flux cancellation with respect to an other one of the first and second inductors.

Example 17 includes the subject matter of any of examples 14-16, and wherein the I and Q path signal lines are part of a quadrature amplitude multiplication circuit in a wireless network chip.

Example 18 is an integrated circuit apparatus that includes first and second differential signal lines and first and second inductors. The first differential signal lines are to receive a first clock. The second differential signal lines are to receive a second clock that is out-of-phase from the first clock by a first phase difference. The first inductor has an input port with first and second ends. The input port is coupled to the first differential signal lines. The second inductor has an output port with first and second ends. The output port is coupled to the second differential lines. The first and second inductors at least partially overlap one another, and a selected one of the first and second inductors has aligned and unaligned flux regions to facilitate flux cancellation with respect to the other of the first and second inductors.

Example 19 includes the subject matter of example 18, and further comprising a switchable cross-coupled capacitor (SCCC) circuit coupled to the first and second lines to compensate for magnetic flux between the first and second inductors.

Example 20 includes the subject matter of any of examples 18-19, and wherein the SCCC circuit includes a plurality of capacitors switchably configured to be in one of multiple different configurations including a first configuration where at least a first capacitor from the plurality of capacitors is coupled between the first ends of the input and output ports.

Example 21 includes the subject matter of any of examples 18-20, and wherein with the first configuration, at least a second capacitor from the plurality of capacitors is coupled between the second ends of the input and output ports.

Example 22 includes the subject matter of any of examples 18-21, and wherein the multiple different configurations include a second configuration where at least a third capacitor from the plurality of capacitors is coupled between the first end of the input port and the second end of the output port.

Example 23 includes the subject matter of any of examples 18-22, and wherein with the second configuration, at least a fourth capacitor from the plurality of capacitors is coupled between the second end of the input port and the first end of the output port.

Example 24 includes the subject matter of any of examples 18-23, and wherein the first and second differential signal lines are part of a clock generation distribution network for an input/output (IO) interface of the integrated circuit.

Example 25 includes the subject matter of any of examples 18-24, and wherein the first phase difference is 90 degrees.

Example 26 is a system that includes a coupled resonator based quadrature hybrid (CRQH) circuit, I and Q path distribution lines, and first and second inductors. The CRQH circuit is to generate I and Q path signals. The I and Q path distribution lines are coupled to the CRQH circuit to buffer the I and Q path signals. The first inductor has an input port with first and second ends. The input port is coupled to the I-path lines. The second inductor has an output port with first and second ends. The output port is coupled to the Q-path lines. The first and second inductors at least partially overlap one another, and a selected one of the first and second inductors has aligned and unaligned flux regions to facilitate flux cancellation with respect to the other of the first and second inductors.

Example 27 includes the subject matter of example 26, and further comprising a switchable cross-coupled capacitor (SCCC) circuit coupled to the I and Q path lines to compensate for magnetic flux between the first and second inductors.

Example 28 includes the subject matter of any of examples 26-27, and wherein the SCCC circuit includes a plurality of capacitors switchably configured to be in one of multiple different configurations including a first configuration where at least a first capacitor from the plurality of capacitors is coupled between the first ends of the input and output ports.

Example 29 includes the subject matter of any of examples 26-28, and wherein with the first configuration, at least a second capacitor from the plurality of capacitors is coupled between the second ends of the input and output ports.

Example 30 includes the subject matter of any of examples 26-29, and wherein the multiple different configurations include a second configuration where at least a third capacitor from the plurality of capacitors is coupled between the first end of the input port and the second end of the output port.

Example 31 includes the subject matter of any of examples 26-30, and wherein with the second configuration, at least a fourth capacitor from the plurality of capacitors is coupled between the second end of the input port and the first end of the output port.

Example 32 includes the subject matter of any of examples 26-31, and wherein the SCCC circuit includes a plurality of capacitors switchably configured to be in one of multiple different configurations including a first configuration where at least a first capacitor from the plurality of capacitors is coupled between the first ends of the input and output ports.

Example 33 includes the subject matter of any of examples 26-32, and wherein with the first configuration, at least a second capacitor from the plurality of capacitors is coupled between the second ends of the input and output ports.

Example 34 includes the subject matter of any of examples 26-33, and wherein the multiple different configurations include a second configuration where at least a third capacitor from the plurality of capacitors is coupled between the first end of the input port and the second end of the output port.

Example 35 includes the subject matter of any of examples 26-34, and wherein with the second configuration, at least a fourth capacitor from the plurality of capacitors is coupled between the second end of the input port and the first end of the output port.

Example 36 includes the subject matter of any of examples 26-35, and further comprising a tunable resistance element coupled to the output port between its first and second ends.

Example 37 includes the subject matter of any of examples 26-36, and wherein the SCCC includes a first tunable capacitor coupled to the input port between its first and second ends and a second tunable capacitor coupled to the output port between its first and second ends.

Example 38 includes the subject matter of any of examples 26-37, and further comprising: (i) a driver coupled to the input port to drive into it a differential I-path clock, and (ii) a Q path line coupled to the output port to convey from it a differential Q path clock generated from the second inductor.

Example 39 is an apparatus that includes a 90 degree hybrid circuit and first and second 45 degree hybrid circuits. The 90 degree hybrid circuit is to generate four quadrature clock signals. The first and second 45 degree hybrid circuits are coupled to the 90 degree hybrid circuit to generate an eight-phase clock output having eight output lines.

Example 40 includes the subject matter of example 39, and further comprising a 45 degree error detection circuit coupled across each of the first and second 45 degree hybrid circuits.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors, or other transistor device types such as carbon nanotubes or spintronic devices.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are dependent upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, a system on a chip (SoC), an application processor, an integrated circuit incorporating a combination of one or more of the aforesaid items, etc.

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a first inductor having an input port with first and second ends;
a second inductor positioned relative to the first inductor to be magnetically coupled with the first inductor, the first and second inductors having an associated effective magnetic coupling factor that has an inductive component, wherein the second inductor has an output port with first and second ends; and
a switchable cross-coupled capacitor (SCCC) circuit coupled to the input and output ports.

2. The apparatus of claim 1, wherein the SCCC circuit includes a plurality of capacitors switchably configured to be in one of multiple different configurations including a first configuration where at least a first capacitor from the plurality of capacitors is coupled between the first ends of the input and output ports.

3. The apparatus of claim 2, wherein with the first configuration, at least a second capacitor from the plurality of capacitors is coupled between the second ends of the input and output ports.

4. The apparatus of claim 2, wherein the multiple different configurations include a second configuration where at least a third capacitor from the plurality of capacitors is coupled between the first end of the input port and the second end of the output port.

5. The apparatus of claim 4, wherein with the second configuration, at least a fourth capacitor from the plurality of capacitors is coupled between the second end of the input port and the first end of the output port.

6. The apparatus of claim 1, further comprising a tunable resistance element coupled to the output port between its first and second ends.

7. The apparatus of claim 1, further comprising a first tunable capacitor coupled to the input port between its first and second ends and a second tunable capacitor coupled to the output port between its first and second ends.

8. The apparatus of claim 1, further comprising: (i) a driver coupled to the input port to drive onto I-path lines a differential I-path clock, and (ii) Q path lines coupled to the output port to convey a differential Q path clock generated from the second inductor.

9. The apparatus of claim 8, further comprising signal averaging circuitry coupled to the I-path and Q-path lines to average together components from the I and Q path clocks.

10. An integrated circuit apparatus, comprising:
differential I-path signal lines to receive a differential I-path clock;
differential Q-path signal lines to receive a differential Q-path clock that is 90 degrees out-of-phase from the I-path clock;
a first inductor coupled to the I-path lines;
a second inductor coupled to the Q-path lines; and
a switchable cross-coupled capacitor (SCCC) circuit coupled to the I-path and Q-path lines.

11. The apparatus of claim 10, wherein the first and second inductors at least partially overlap one another.

12. The apparatus of claim 11, wherein a selected one of the first and second inductors has aligned and unaligned flux regions to facilitate flux cancellation with respect to an other one of the first and second inductors.

13. The apparatus of claim 10, wherein the I and Q path signal lines are part of a quadrature amplitude multiplication circuit in a wireless network chip.

14. An integrated circuit apparatus, comprising:
first differential signal lines to receive a first clock;
second differential signal lines to receive a second clock that is to be out-of-phase from the first clock by a first phase difference;
a first inductor having an input port with first and second ends, the input port coupled to the first differential lines; and
a second inductor having an output port with first and second ends, the output port coupled to the second differential lines, wherein the first and second inductors at least partially overlap one another, and a selected one of the first and second inductors has aligned and unaligned flux regions to facilitate flux cancellation with respect to the other of the first and second inductors.

15. The apparatus of claim 14, further comprising a switchable cross-coupled capacitor (SCCC) circuit coupled to the first and second lines to compensate for magnetic flux between the first and second inductors.

16. The apparatus of claim 15, wherein the SCCC circuit includes a plurality of capacitors switchably configured to be in one of multiple different configurations including a first configuration where at least a first capacitor from the plurality of capacitors is coupled between the first ends of the input and output ports.

17. The apparatus of claim 16, wherein with the first configuration, at least a second capacitor from the plurality of capacitors is coupled between the second ends of the input and output ports.

18. The apparatus of claim 16, wherein the multiple different configurations include a second configuration where at least a third capacitor from the plurality of capacitors is coupled between the first end of the input port and the second end of the output port.

19. The apparatus of claim 18, wherein with the second configuration, at least a fourth capacitor from the plurality of capacitors is coupled between the second end of the input port and the first end of the output port.

20. The apparatus of claim 15, wherein the first and second differential signal lines are part of a clock generation distribution network for an input/output (IO) interface of the integrated circuit.
